(19) United States
(12) Patent Application Publication
(10) Pub. No.: US 2026/0262388 A1
(43) Pub. Date: Sep. 3, 2026

(54) Display Panel, Method for Manufacturing Display Panel and Display Apparatus

(71) Applicants: BOE TECHNOLOGY GROUP CO., LTD., Chaoyang District, Beijing (CN); CHENGDU BOE OPTOELECTRONICS TECHNOLOGY CO., LTD., Chengdu, Sichuan (CN)

(72) Inventors: Kening Zheng, Beijing (CN); Jiayu Wang, Beijing (CN); Xuenan Pan, Beijing (CN); Dengyu Wang, Beijing (CN); Langtao Li, Beijing (CN); Tong Wu, Beijing (CN)

(21) Appl. No.: 18/993,147

(22) PCT Filed: Apr. 25, 2024
(86) PCT No.: PCT/CN2024/089823

§ 371 Date: Jan. 10, 2025

(51) Int. Cl. H10K 59/122; H10K 59/12; H10K 59/126; H10K 59/38; H10K 59/80

(52) U.S. Cl. CPC H10K 59/122; H10K 59/1201; H10K 59/126; H10K 59/38; H10K 59/8731

(57) ABSTRACT

A display panel includes a substrate, an isolation structure, an encapsulation structure and an optical structure. The isolation structure is located on a side of the substrate, and the isolation structure defines a plurality of pixel openings. A light-emitting device is disposed in a pixel opening. The encapsulation layer includes a first inorganic encapsulation layer, an organic encapsulation layer and a second inorganic encapsulation layer that are stacked in sequence in a direction away from the substrate. The optical structure is located between the first inorganic encapsulation layer and the organic encapsulation layer. The optical structure includes a plurality of light-transmissive optical portions, and a single optical portion is located in a single pixel opening.

### CROSS-REFERENCE TO RELATED APPLICATION

This application is the United States national phase of International Patent Application No. PCT/CN2024/089823, filed Apr. 25, 2024, the disclosure of which is hereby incorporated by reference in its entirety.

### BACKGROUND OF THE INVENTION

### Field of the Invention

The present disclosure relates to the field of display technologies, and in particular, to a display panel, a method for manufacturing a display panel, and a display apparatus.

### Description of Related Art

With the continuous development of display technologies, display apparatuses have gradually come throughout people's lives. Organic light-emitting diode (OLED) display panels are widely used in display apparatuses such as mobile phones, televisions, and notebook computers due to the advantages of self-illumination, low power consumption, wide viewing angle, fast response, and high contrast.

### SUMMARY OF THE INVENTION

In an aspect, a display panel is provided. The display panel includes a substrate, an isolation structure, an encapsulation structure and an optical structure.

The isolation structure is located on a side of the substrate, and the isolation structure defines a plurality of pixel openings; and a light-emitting device is disposed in a pixel opening. The encapsulation structure is located on a side of the light-emitting devices away from the substrate. The encapsulation structure includes a first inorganic encapsulation layer, an organic encapsulation layer and a second inorganic encapsulation layer that are stacked in sequence in a direction away from the substrate.

The optical structure is located between the first inorganic encapsulation layer and the organic encapsulation layer. The optical structure includes a plurality of light-transmissive optical portions, and a single optical portion is located in a single pixel opening.

In some embodiments, a surface of the optical portion away from the substrate is closer to the substrate than a surface of the isolation structure away from the substrate; or, the surface of the optical portion away from the substrate is flush with the surface of the isolation structure away from the substrate.

In some embodiments, the isolation structure includes a first sub-layer, a second sub-layer and a third sub-layer that are stacked in sequence in the direction away from the substrate. A surface of the optical portion away from the substrate is farther away from the substrate than a surface of the second sub-layer away from the substrate.

In some embodiments, a refractive index of a material of the optical portion is different from a refractive index of a material of the third sub-layer.

In some embodiments, a refractive index of the optical portion is greater than or equal to 1.65, and a refractive index of the third sub-layer is less than or equal to 1.4; or, the refractive index of the optical portion is less than or equal to 1.4, and the refractive index of the third sub-layer is greater than or equal to 1.65.

In some embodiments, a material of the optical portion includes photoresist.

In some embodiments, the optical portion includes first particles, and a refractive index of the first particles is in a range of 1 to 2.

In some embodiments, the optical portion is a filter color resist; and for a light-emitting device and a filter color resist that are located in a same pixel opening, a color of light transmitted by the filter color resist is the same as a color of light emitted by the light-emitting device.

In some embodiments, the isolation structure includes a first sub-layer, a second sub-layer and a third sub-layer that are stacked in sequence in the direction away from the substrate. At least the third sub-layer in the isolation structure includes a light-shielding material.

In some embodiments, the second sub-layer includes a light-shielding material, and the third sub-layer includes a light-shielding material.

In some embodiments, a first sub-layer of the isolation structure includes an insulating material, a third sub-layer of the isolation structure includes an insulating material, and a second sub-layer of the isolation structure includes a conductive material.

The light-emitting device includes a first electrode, a light-emitting portion and a second electrode that are stacked in sequence in the direction away from the substrate; and second electrodes of two adjacent light-emitting devices are connected through a portion of the second sub-layer of the isolation structure located between the two adjacent light-emitting devices.

In some embodiments, a surface of the isolation structure away from the substrate is provided with a plurality of grooves, and a groove is communicated with at least one pixel opening.

In some embodiments, at least one groove is arranged between two adjacent pixel openings, and the at least one groove is communicated with the two adjacent pixel openings.

In some embodiments, one pixel opening is communicated with grooves, the grooves each extend in a direction away from the pixel opening, and the grooves are arranged around the pixel opening and arranged at intervals.

In some embodiments, along a direction in which the grooves surround the pixel opening, a distance between two adjacent grooves is equal.

In some embodiments, a depth of the groove is less than or equal to a thickness of the third sub-layer of the isolation structure.

In some embodiments, a material of the third sub-layer of the isolation structure includes a hydrophobic material or an oleophobic material; and a material of the optical structure includes a hydrophobic material or an oleophobic material.

In some embodiments, the isolation structure includes a first sub-layer, a second sub-layer and a third sub-layer that are stacked in sequence in the direction away from the substrate.

The light-emitting device includes a first electrode, a light-emitting portion and a second electrode that are stacked in sequence in the direction away from the substrate.

The first sub-layer covers a part of the first electrode.

In yet another aspect, a method for manufacturing a display panel is provided, which includes the following steps.

An isolation structure is formed on a side of the substrate, and the isolation structure defines a plurality of pixel openings.

A target color light-emitting device film layer and a first inorganic thin film are sequentially formed on the substrate on which the plurality of pixel openings have been formed.

A photoresist layer is formed on a side of the first inorganic thin film away from the substrate, and the photoresist layer covers regions of target color light-emitting devices.

Based on the photoresist layer, portions, covering a region other than the regions of the target color light-emitting devices, of the target color light-emitting device film layer and the first inorganic thin film are removed, so that remaining portions of the target color light-emitting device film layer in the regions of the target color light-emitting devices form the target color light-emitting devices, remaining portions of the first inorganic thin film in the regions of the target color light-emitting devices form corresponding portions of a first inorganic encapsulation layer, and remaining portions of the photoresist layer form a part of an optical structure.

In yet another aspect, a display apparatus is provided, which includes the display panel as described in any of the above embodiments and a cover plate.

The cover plate is disposed on a light exit side of the display panel.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a sectional view of the display apparatus in FIG. 1 taken along the line B-B;

FIG. 3 is a structural diagram of a display panel, in accordance with some embodiments;

FIG. 4A is a diagram showing a film layer structure of a light-emitting device, in accordance with some embodiments;

FIG. 4B is a diagram showing a film layer structure of a light-emitting device, in accordance with some other embodiments;

FIG. 4C is a diagram showing a film layer structure of a light-emitting device, in accordance with yet some other embodiments;

FIG. 4D is a diagram showing a film layer structure of a light-emitting device, in accordance with yet some other embodiments;

FIG. 5 is another sectional view of the display apparatus in FIG. 1 taken along the line B-B;

FIG. 6 a plan view showing a partial structure of a display panel, in accordance with some embodiments;

FIG. 7 is a sectional view of an isolation structure, in accordance with some embodiments;

FIG. 8A is a structural diagram of another display apparatus, in accordance with some embodiments;

FIG. 8B is a structural diagram of yet another display apparatus, in accordance with some embodiments;

FIG. 8C is a structural diagram of yet another display apparatus, in accordance with some embodiments;

FIG. 9 is a structural diagram of another display panel, in accordance with some embodiments;

FIG. 10 is a schematic diagram showing a transmittance curve of an optical portion of an optical structure in a display panel for light of different bands, in accordance with some embodiments;

FIG. 11 is a structural diagram of yet another display panel, in accordance with some embodiments;

FIG. 12 is a schematic diagram showing a thickness variation trend of an organic encapsulation layer of an encapsulation structure in a direction from an edge to a center of a display panel;

FIG. 13 is a plan view showing a partial structure of an isolation structure, in accordance with some embodiments;

FIG. 14 is a plan view showing a partial structure of an isolation structure, in accordance with some other embodiments;

FIG. 15A is a sectional view of the isolation structure in FIG. 13 taken along the line C-C;

FIG. 15B is another sectional view of the isolation structure in FIG. 13 taken along the line C-C;

FIG. 16 is a flow diagram of a method for manufacturing a display panel, in accordance with some embodiments;

FIG. 17 is a diagram showing a structure corresponding to a step S1 of a method for manufacturing a display panel according to an embodiment shown in FIG. 16;

FIG. 18 is a diagram showing a structure corresponding to a step S2 of a method for manufacturing a display panel according to an embodiment shown in FIG. 16;

FIG. 19 is a diagram showing a structure corresponding to a step S3 of a method for manufacturing a display panel according to an embodiment shown in FIG. 16;

FIG. 20 is a diagram showing a structure corresponding to a step S4 of a method for manufacturing a display panel according to an embodiment shown in FIG. 16;

FIG. 21 is a diagram showing a structure corresponding to a step S2 of another method for manufacturing a display panel according to an embodiment shown in FIG. 16;

FIG. 22 is a diagram showing a structure corresponding to a step S3 of another method for manufacturing a display panel according to an embodiment shown in FIG. 16;

FIG. 23 is a diagram showing a structure corresponding to a step S4 of another method for manufacturing a display panel according to an embodiment shown in FIG. 16;

FIG. 24 is a diagram showing a structure corresponding to a step S2 of yet another method for manufacturing a display panel according to an embodiment shown in FIG. 16;

FIG. 25 is a diagram showing a structure corresponding to a step S3 of yet another method for manufacturing a display panel according to an embodiment shown in FIG. 16;

FIG. 26 is a diagram showing a structure corresponding to a step S4 of yet another method for manufacturing a display panel according to an embodiment shown in FIG. 16;

FIG. 27 is a diagram showing a structure corresponding to a step S2 of yet another method for manufacturing a display panel according to an embodiment shown in FIG. 16;

FIG. 28 is a diagram showing a structure corresponding to a step S3 of yet another method for manufacturing a display panel according to an embodiment shown in FIG. 16; and

FIG. 29 is a diagram showing a structure corresponding to a step S4 of yet another method for manufacturing a display panel according to an embodiment shown in FIG. 16.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that two or more components are in direct physical or electrical contact with each other. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

As used herein, the term “if” is optionally construed as “when” or “in a case where” or “in response to determining” or “in response to detecting”, depending on the context. Similarly, depending on the context, the phrase “if it is determined that” or “if [a stated condition or event] is detected” is optionally construed as “in a case where it is determined that”, “in response to determining that”, “in a case where [the stated condition or event] is detected” or “in response to detecting [the stated condition or event]”.

The phrase “applicable to” or “configured to” used herein has an open and inclusive meaning, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or value exceeding those stated.

The term such as “about,” “substantially,” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

For the convenience of the following description, an XYZ coordinate system is established. A third direction Z is a thickness direction of a display apparatus, an XY plane is perpendicular to the Z direction, and a first direction X and a second direction Y intersect. For example, the first direction X and the second direction Y are perpendicular to each other.

It will be noted that, for example, F1/F shown in the accompanying drawings of the present disclosure indicates that a component is both F1 and F, and other similar symbols shown in the accompanying drawings also follow the above explanation.

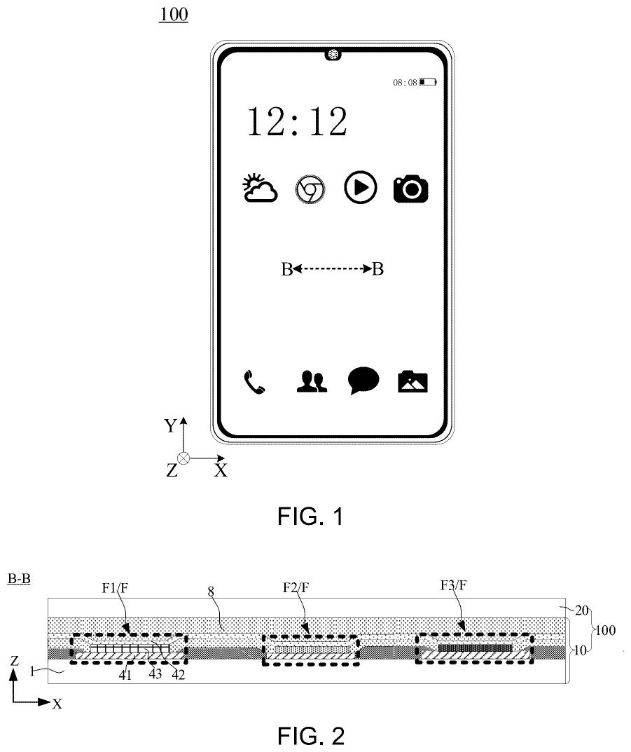

As shown in FIG. 1, some embodiments of the present disclosure provide a display apparatus 100.

For example, the display apparatus 100 may be any apparatus that displays images whether in motion (e.g., videos) or stationary (e.g., static images), and whether literal or graphical. More specifically, it is expected that the embodiments may be implemented in or associated with a plurality of electronic devices. The plurality of electronic devices may include (but are not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays, etc.), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc. FIG. 1 is illustrated by taking an example in which the display apparatus 100 is a mobile phone.

The display apparatus 100 may be an electroluminescent display apparatus or a photoluminescence display apparatus. In the case where the display apparatus 100 is an electroluminescent display apparatus, the electroluminescent display apparatus may be an organic light-emitting diode (OLED) display apparatus or a quantum dot light-emitting diode (QLED) display apparatus. In the case where the display apparatus 100 is a photoluminescent display apparatus, the photoluminescent display apparatus may be a quantum dot photoluminescent display apparatus.

Some embodiments of the present disclosure will be schematically described below by taking an example in which the display apparatus 100 is an OLED display apparatus. However, the implementations of the present disclosure include but are not limited to this, and any other display apparatus may also be considered as long as the same technical concept is applied.

In some embodiments, as shown in FIG. 2, FIG. 2 is a sectional view of the display apparatus 100 in FIG. 1 taken along the line B-B. The display apparatus 100 includes a display panel 10 and a cover plate 20. The cover plate 20 is disposed on a light exit side of the display panel 10.

The cover plate 20 may separate the display panel 10 from an external environment and protect the display panel 10.

For example, the cover plate 20 may be a single-layer cover plate, or may be a cover plate 20 in which multiple layers are laminated together through an adhesive material.

For example, the cover plate 20 may be a silicate glass cover plate, such as curved glass or ultra-thin glass.

The cover plate 20 may also be a flexible polymer film cover plate, such as transparent polyimide, polyethylene terephthalate (PET) or polyurethane.

The cover plate 20 may also be a combination of the above-mentioned flexible polymer films, or a combination of a flexible polymer film and silicate glass.

In some embodiments, the display apparatus 100 may further include a circuit board (not shown in figures). The circuit board is electrically connected to the display panel 10, and is configured to drive the display panel 10 to display images.

For example, the circuit board includes but is not limited to a printed circuit board (PCB) and a flexible printed circuit board (FPC).

In some embodiments, the display apparatus 100 may further include an under-screen camera, an under-screen fingerprint recognition sensor, etc., so that the display apparatus 100 can implement various functions such as photographing, video recording, fingerprint recognition, or face recognition, which will not be limited in the present disclosure and can be adaptively designed according to actual needs.

The display panel 10 will be described in detail below.

In some embodiments, with continued reference to FIG. 2, the display panel 10 includes a substrate 1.

For example, a material for forming the substrate 1 may include an inorganic material, e.g., a glass material such as soda-lime glass, quartz glass, or sapphire glass.

The material for forming the substrate 1 may also include an organic material, e.g., one or more of polymethyl methacrylate, polyvinyl alcohol, polyvinyl phenol, polyether sulfone, polyimide, polyamide, polyacetal, polycarbonate, polyethylene terephthalate, and polyethylene naphthalate.

The material for forming the substrate 1 may also include both an organic material and an inorganic material.

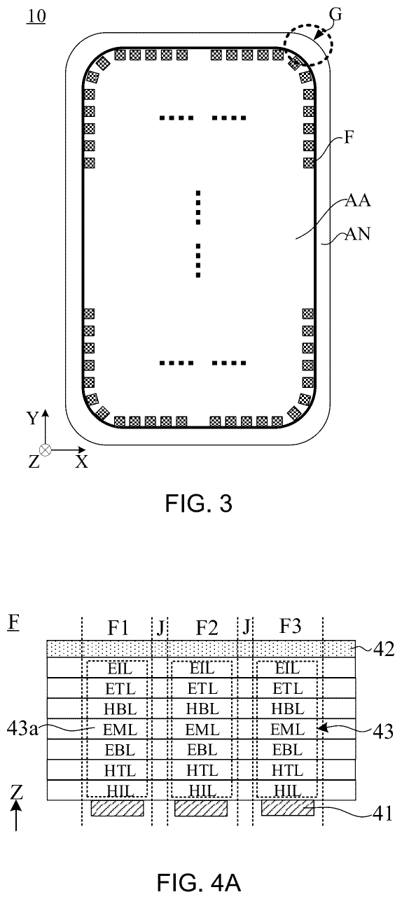

In some embodiments, as shown in FIG. 3, FIG. 3 is a structural diagram of a display panel 10 according to some embodiments. The display panel 10 may be of a rectangular structure.

It will be noted that, the term “rectangular structure” means that a border of the display panel 10 is in a shape of a rectangle as a whole, but is not limited to a standard rectangle. That is, “rectangle” herein includes not only a standard rectangle but also a shape similar to the rectangle in consideration of process conditions. For example, as shown in FIG. 3, long and short sides of the rectangle are curved at each intersecting position (i.e. corners G), that is, the corners G are smooth, so that the border of the display panel 10 is in a shape of a rounded rectangle in a plan view.

In some other embodiments, the display panel 10 may be of a circular structure, or other shapes with corners.

Some embodiments of the present disclosure will be schematically described below by taking an example the display panel 10 is of a rectangular structure. However, the implementations of the present disclosure include but are not limited to this, and the shape display panel 10 may also be any other shape.

In some embodiments, with continued reference to FIG. 3, the display panel 10 has a display region AA for displaying images and a peripheral region AN located on at least one side of the display region AA.

For example, the peripheral region AN is located on one side of the display region AA.

For another example, the peripheral region AN is located on two opposite sides of the display region AA.

For yet another example, as shown in FIG. 3, the peripheral region AN surrounds the display region AA.

It will be noted that the specific arrangement of the peripheral region AN is related to the specific design of the display panel 10, which can be designed according to actual needs. This is only used as an exemplary description and is not intended to limit the present disclosure.

In some embodiments, with continued reference to FIGS. 2 and 3, the display region AA of the display panel 10 is provided therein with a plurality of light-emitting devices F. The light-emitting devices F are the smallest light-emitting units in the display region AA. The plurality of light-emitting devices F in the display region AA of the display panel 10 are located on one side of the substrate 1.

For example, other film layer structures may be provided between the substrate 1 and the light-emitting devices F.

For example, a driving layer (not shown in the figure) for driving the light-emitting devices F to emit light may be provided between the substrate 1 and the light-emitting devices F. The driving layer may include: an active layer (Active) formed on the substrate 1 by a patterning process, a gate insulating layer (GI) formed on the active layer (Active) by deposition or the like, gates (Gate) of thin film transistors (TFT) formed on the gate insulating layer (GI) by a patterning process, a dielectric layer (ILD) formed on the gates (Gate) by deposition or the like, a source-drain metal layer formed on the dielectric layer (ILD), and a planarization layer (PLN) covering the source-drain metal layer and exposing the dielectric layer (ILD); and the source-drain metal layer forms sources (Source) and drains (Drain) of the thin film transistors (TFT).

A material of the active layer (Active) may include polysilicon and metal oxide. A material of the gate insulating layer (GI) may include an inorganic insulating material such as silicon oxide, silicon nitride or silicon oxynitride. A material of the dielectric layer (ILD) may include an inorganic insulating material such as silicon oxide, silicon nitride or silicon oxynitride. A material of the gates (Gate) may include metal such as aluminum, titanium and cobalt, or an alloy material. A material of the planarization layer (PLN) may include an organic material, or may include an inorganic insulating material such as silicon oxide, silicon nitride or silicon oxynitride. The planarization layer (PLN) has a flattening effect, which is conducive to improving the quality of subsequent material deposition and reducing difference in surface of other film layers formed subsequently. The planarization layer (PLN) can block water and oxygen from entering the light-emitting devices F.

For example, the plurality of light-emitting devices F in the display region AA of the display panel 10 may emit light of the same color, and the display panel 10 may further include a color filter layer disposed on a light exit side of the plurality of light-emitting devices F. For example, the plurality of light-emitting devices F all emit color light, such as white light, red light, green light or blue light. In this case, after passing through the color filter layer, the color light emitted by the light-emitting device F remains the same color light, or is converted into other color light and exits. Therefore, when the plurality of light-emitting devices F emit light of the same color, the display panel 10 may achieve multi-color light emission.

Alternatively, as shown in FIG. 2, the plurality of light-emitting devices F in the display region AA of the display panel 10 emit light of different colors. For example, the plurality of light-emitting devices F include first color light-emitting devices F1 that emit light of a first color, second color light-emitting devices F2 that emit light of a second color, and third color light-emitting devices F3 that emit light of a third color, thereby realizing multi-color light emission of the display panel 10.

The first color light-emitting devices F1 may be red light-emitting devices, which emit red light. The second color light-emitting devices F2 may be green light-emitting devices, which emit green light. The third color light-emitting devices F3 may be blue light-emitting devices, which emit blue light.

Alternatively, the first color light-emitting devices F1 may be green light-emitting devices or blue light-emitting devices. The second color light-emitting devices F2 may be red light-emitting devices or blue light-emitting devices. The third color light-emitting devices F3 may be red light-emitting devices or green light-emitting devices.

Some embodiments of the present disclosure will be schematically described below by taking an example in which the plurality of light-emitting devices F in the display region AA of the display panel 10 emit light of different colors.

In some embodiments, with continued reference to FIG. 2, the light-emitting device F includes a first electrode 41, a light-emitting portion 43 and a second electrode 42 that are stacked in sequence in a direction away from the substrate 1. That is, the first electrode 41 is closer to the substrate 1 than the second electrode 42.

The first electrode 41 and the second electrode 42 can provide carriers (such as electrons and holes) to the light-emitting portion 43, so that the light-emitting portion 43 emits light.

For example, one of the first electrode 41 and the second electrode 42 is used as an anode of the light-emitting device F (e.g., the first color light-emitting device F1, the second color light-emitting device F2, and the third color light-emitting device F3), and another of the first electrode 41 and the second electrode 42 is used as a cathode of the light-emitting device F (e.g., the first color light-emitting device F1, the second color light-emitting device F2, and the third color light-emitting device F3).

For example, the first electrode 41 is used as the anode of the light-emitting device F (e.g., the first color light-emitting device F1, the second color light-emitting device F2, and the third color light-emitting device F3), and the second electrode 42 is used as the cathode of the light-emitting device F (e.g., the first color light-emitting device F1, the second color light-emitting device F2, and the third color light-emitting device F3).

For example, a material for forming the first electrode 41 may include a metal material, such as any one or more of magnesium (Mg), silver (Ag), copper (Cu), aluminum (Al), titanium (Ti), and molybdenum (Mo).

The material for forming the first electrode 41 may also include an alloy material of the above metal material, such as an aluminum—neodymium alloy (AlNd) or a molybdenum—niobium alloy (MoNb).

For example, the first electrode 41 may be of a single-layer structure.

Alternatively, the first electrode 41 may be of a multi-layer composite structure. For example, the first electrode 41 may be of a Ti/Al/Ti structure or the like. For another example, the first electrode 41 may be a stack structure formed by a metal material and a transparent conductive material, such as ITO/Ag/ITO, Mo/AlNd/ITO, etc.

For example, a material for forming the second electrode 42 may include may include any one or more of magnesium (Mg), silver (Ag), aluminum (Al), etc.

The material for forming the second electrode 42 may also include an alloy made of any one or more of magnesium (Mg), silver (Ag), aluminum (Al), etc.

The material for forming the second electrode 42 may also include a transparent conductive material, such as indium tin oxide (ITO).

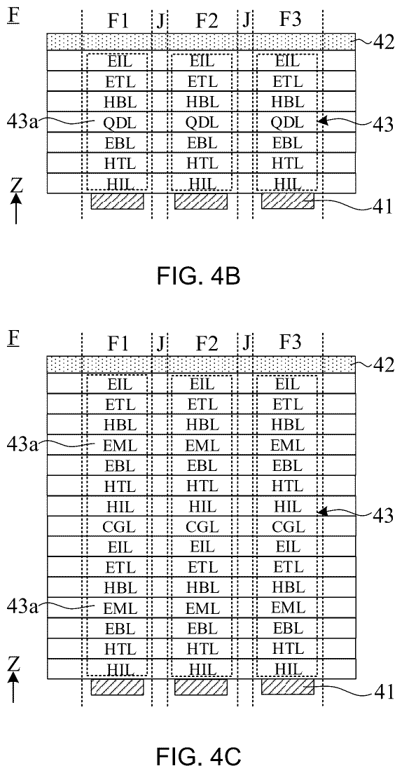

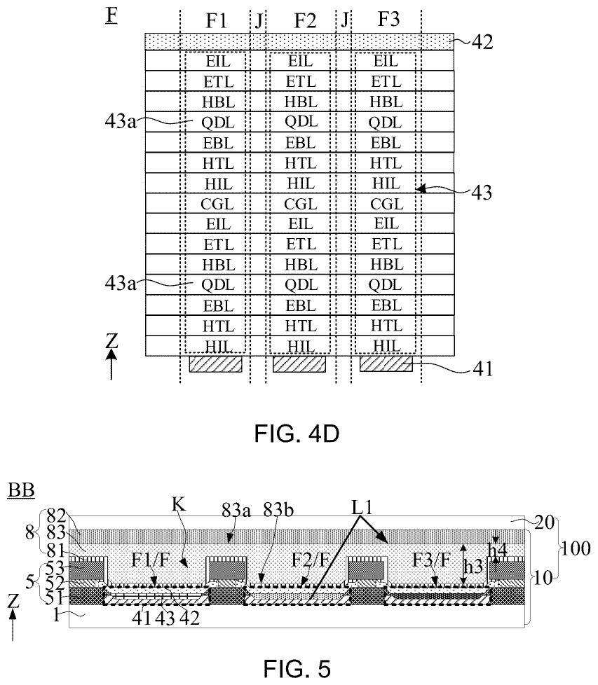

In some embodiments, as shown in FIGS. 4A, 4B, 4C, and 4D, FIGS. 4A, 4B, 4C, and 4D are each a diagram showing a film layer structure of a light-emitting device F according to some embodiments. The light-emitting portion 43 in the light-emitting device F includes a light-emitting layer 43a.

For example, with continued reference to FIGS. 4A and 4C, the display panel 10 may be an OLED display panel. Since the display panel 10 is an OLED display panel, the light-emitting layer 43a may include an organic light-emitting layer (EML). For example, the organic light-emitting layer EML may include a light-emitting layer host material and a light-emitting layer guest material, and the light-emitting layer guest material may be a fluorescent dopant or a phosphorescent dopant.

Alternatively, with continued reference to FIGS. 4B and 4D, the display panel 10 may be a QLED display panel. Since the display panel 10 is a QLED display panel, the light-emitting layer 43a may include a quantum dot layer (QDL). For example, a quantum dot layer (QDL) may have quantum dot particles, and the quantum dot particles may be interconnected via surface modifying groups. For example, with continued reference to FIGS. 4A, 4B, 4C and 4D, the light-emitting portion 43 may further include one or more of a hole injection layer (HIL), a hole transport layer (HTL), an electron blocking layer (EBL), a hole blocking layer (HBL), an electron transport layer (ETL) and an electron injection layer (EIL).

In some embodiments, with continued reference to FIGS. 4A and 4B, the light-emitting portion 43 in the light-emitting device F may include a single light-emitting layer 43a.

In some other embodiments, with continued reference to FIGS. 4C and 4D, the light-emitting portion 43 in the light-emitting device F may include a plurality of light-emitting layers 43a.

For example, with continued reference to FIGS. 4C and 4D, the light-emitting portion 43 in the light-emitting device F may include two light-emitting layers 43a.

With continued reference to FIGS. 4C and 4D, the light-emitting portion 43 in the light-emitting device F further includes a charge generation layer (CGL) located between two adjacent light-emitting layers 43a. The charge generation layer (CGL) can connect the two adjacent light-emitting layers 43a in series, thereby realizing a tandem EL design.

Since the number of light-emitting layers 43a increases and the charge generation layer (CGL) may reduce a driving voltage and generate new carriers, the light-emitting efficiency of the light-emitting portion 43 may be multiplied. In addition, at the same luminance, compared with a display panel 10 with a single-layer EL design, the display panel 10 with the tandem EL design has a lower current density, which is conducive to extending the service life of the display panel 10.

For example, the charge generation layer (CGL) may be configured to generate carriers, transport carriers, and inject carriers.

For example, the charge generation layer (CGL) may include an N-type charge generation layer (n-CGL) and a P-type charge generation layer (p-CGL).

The N-type charge generation layer (n-CGL) may include, for example, an organic electron transport layer (ETL) material doped with a metal material.

The P-type charge generation layer (p-CGL) may include, for example, an organic hole transport layer (HTL) material doped with a p-type light-emitting dopant (p-dopant or PD).

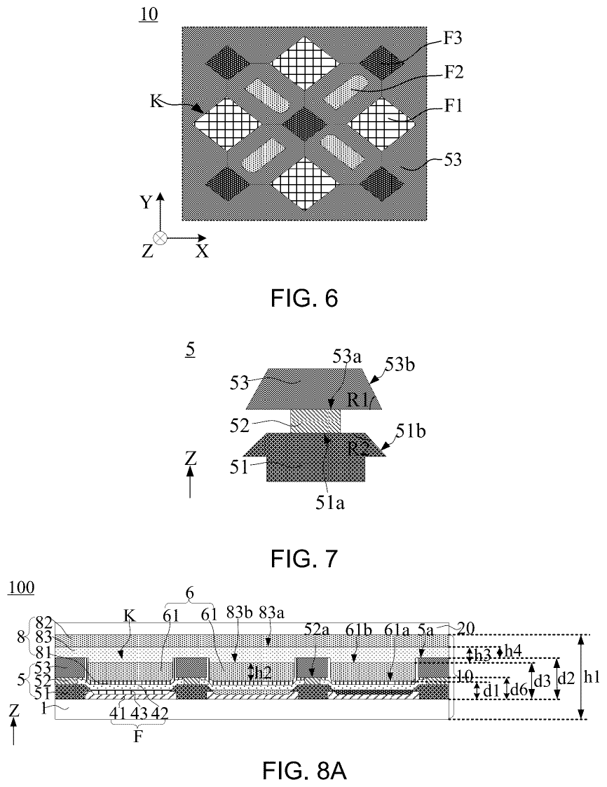

In some embodiments, as shown in FIGS. 5 and 6, FIG. 5 is another sectional view of the display apparatus 100 in FIG. 1 taken along the line B-B, and FIG. 6 is a plan view showing a partial structure of a display panel 10 according to some embodiments. The display panel 10 further includes an isolation structure 5. The isolation structure 5 is located on a side of the substrate 1 and defines a plurality of pixel openings K. A light-emitting device F (e.g., a first color light-emitting device F1, a second color light-emitting device F2 or a third color light-emitting device F3) is disposed in a pixel opening K, and one pixel opening K corresponds to one light-emitting device F (e.g., one first color light-emitting device F1, one second color light-emitting device F2 or one third color light-emitting device F3).

By providing the isolation structure 5 and arranging one light-emitting device F (for example, the first color light-emitting device F1, the second color light-emitting device F2 or the third color light-emitting device F3) in one pixel opening K of the isolation structure 5, light-emitting portions 43 of two adjacent light-emitting devices F may be disconnected at the isolation structure 5.

For example, the pixel opening K may be of a rectangular structure, a circular structure, or other shapes with corners.

In some embodiments, with continued reference to FIG. 5, the isolation structure 5 includes a first sub-layer 51, a second sub-layer 52, and a third sub-layer 53 that are stacked in sequence in the direction away from the substrate 1. That is, the first sub-layer 51 is closer to the substrate 1 than the third sub-layer 53.

A material of the first sub-layer 51 may include an insulating material, a material of the third sub-layer 53 may include an insulating material, and a material of the second sub-layer 52 may include a conductive material.

For example, the material of the first sub-layer 51 may be an organic insulating material, such as polyimide, acrylic or polyethylene terephthalate.

The material of the third sub-layer 53 may include an inorganic insulating material, such as silicon oxide, silicon dioxide, silicon nitride or carbon black.

The material of the second sub-layer 52 may include metal, such as titanium nitride. In some embodiments, with continued reference to FIG. 5, since the material of the second sub-layer 52 includes a conductive material, second electrodes 42 of two adjacent light-emitting devices F may be connected through a portion of the second sub-layer 52 of the isolation structure 5 located between the two adjacent light-emitting devices F, which facilitates the signal transmission between the second electrodes (for example, cathodes) of the two adjacent light-emitting devices F.

In some embodiments, with continued reference to FIG. 5, the first sub-layer 51 of the isolation structure 5 covers a part of the first electrode 41 of the light-emitting device F.

The first sub-layer 51 of the isolation structure 5 covers a part of the first electrode 41 of the light-emitting device F, that is, the pixel opening K defined by the isolation structure 5 exposes a part of the first electrode 41. Therefore, the first sub-layer 51 of the isolation structure 5 may effectively define an actual effective part of the first electrode 41 (that is, a part of the first electrode 41 that is directly electrically connected to the light-emitting portion 43), and in turn may define a light-emitting region and a light-emitting area of the sub-pixel F.

For example, the first sub-layer 51 of the isolation structure 5 may cover an edge of the first electrode 41 of the light-emitting device F.

For example, as shown in FIG. 7, FIG. 7 is a sectional view of an isolation structure 5 according to some embodiments. A surface 53a of the third sub-layer 53 close to the second sub-layer 52 and a side surface 53b of the third sub-layer 53 have a first included angle R1 therebetween. The first included angle R1 faces towards an interior of the third sub-layer 53. The first included angle R1 is greater than 45° and less than 90°.

For example, the first included angle R1 may be 46°, 50°, 55°, 60°, 66°, 70°, 75°, 80°, 85°, 86°, 88 ° or 89°.

Since the first angle R1 is set to be greater than 45 ° and less than 90°, the section of the third sub-layer 53 is set to be in a shape of an upright trapezoid, which facilitates depositing the material for forming the second electrode 42 on the sidewall of the second sub-layer 52, which improves the overlap yield of the second electrodes 42 and the second sub-layer 52.

For example, with continued reference to FIG. 7, a surface 51a of the first sub-layer 51 close to the second sub-layer 52 and a side surface 51b of the first sub-layer 51 have a second included angle R2 therebetween, and the second included angle R2 faces towards an interior of the first sub-layer 51. The second included angle R2 is greater than 90° and less than 180°.

For example, the second included angle R2 may be 93°, 100°, 105°, 110°, 115°, 120°, 126°, 130°, 135°, 140°, 145°, 150°, 155°, 160°, 165°, 170°, 175° or 178°. In some embodiments, with continuous reference to FIG. 5, the display panel 10 further includes an encapsulation structure 8. The encapsulation structure 8 is located on a side of the plurality of light-emitting devices F away from the substrate 1. That is, the encapsulation structure 8 is farther away from the substrate 1 than the light-emitting devices F.

The encapsulation structure 8 includes a first inorganic encapsulation layer 81, an organic encapsulation layer 83 and a second inorganic encapsulation layer 82 that are stacked in sequence in the direction away from the substrate 1. That is, the first inorganic encapsulation layer 81 is closer to the light-emitting devices F than the second inorganic encapsulation layer 82.

The encapsulation structure 8 is used for encapsulating the light-emitting devices F (e.g., the first color light-emitting devices F1, the second color light-emitting devices F2, and the third color light-emitting devices F3) to protect the light-emitting devices F and avoid corrosion caused by external water and oxygen.

The first inorganic encapsulation layer 81 and the second inorganic encapsulation layer 82 are made of inorganic materials, which may be used for blocking water and oxygen. The organic encapsulation layer 83 is made of an organic material, which may play the role of flattening surface, covering defects and releasing stress.

For example, the materials of the first inorganic encapsulating layer 81 and the second inorganic encapsulating layer 82 may each include an alkali metal compound (e.g., LiF), an alkaline earth metal compound (e.g., MgF₂), SiON, SiNₓ, or SiO_{y}.

The material of the organic encapsulation layer 83 may include organic ink or the like.

For example, the first inorganic encapsulation layer 81 and the second inorganic encapsulation layer 82 may be formed by using processes such as plasma enhanced chemical vapor deposition (PECVD), magnetron sputtering (SUPTTER) or atomic layer deposition (ALD).

The organic encapsulation layer 83 may be formed by using processes such as inkjet printing (IJP), plasma enhanced chemical vapor deposition (PECVD), screen printing, or flash evaporation.

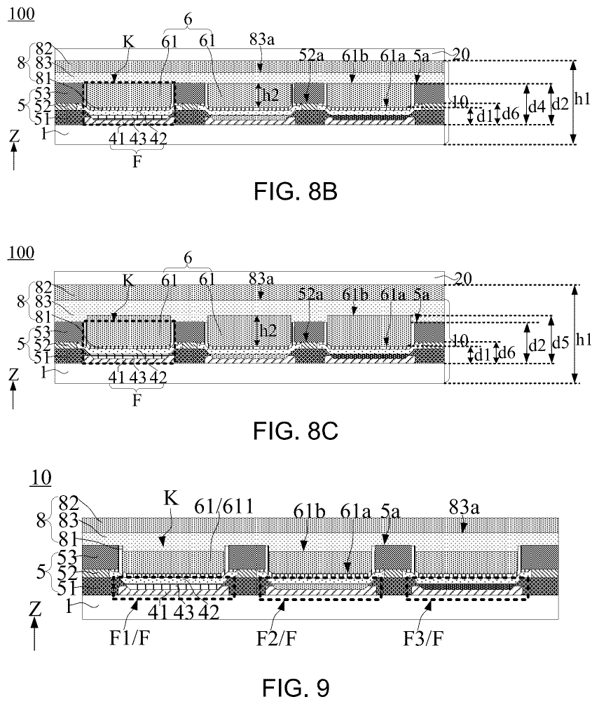

In some embodiments, as shown in FIGS. 8A, 8B and 8C, FIGS. 8A, 8B and 8C are each a structural diagram of a display apparatus 100 according to some embodiments. The display panel 10 further includes an optical structure 6. The optical structure 6 includes a plurality of light-transmissive optical portions 61, and an optical portion 61 is located on a light exit side of a light-emitting device F.

For example, the optical structure 6 may be used for forming an enhanced efficiency structure (EES), which is conducive to improving the light extraction efficiency of the display panel 10. The implementation manner of using the optical structure 6 to form the enhanced efficiency structure (EES) and the principle of improving the light extraction efficiency of the display panel 10 will be described in detail later.

The optical structure 6 may also be used for forming a color filter on encapsulation (COE) structure, which is conducive to improving the light transmittance. The implementation manner of using the optical structure 6 to form the color filter on encapsulation (COE) structure and the principle of improving light transmittance will be described in detail later.

In some embodiments, with continued reference to FIGS. 8A, 8B and 8C, an optical portion 61 is located in a pixel opening K; and a surface 61a of the optical portion 61 close to the substrate 1 is closer to the substrate 1 than a surface 5a of the isolation structure 5 away from the substrate 1. That is, a distance d1 between the surface 61a of the optical portion 61 close to the substrate 1 and the substrate 1 is less than a distance d2 between the surface 5a of the isolation structure 5 away from the substrate 1 and the substrate 1.

That is, at least part of an optical portion 61 is located within a pixel opening K. Compared with the case where the optical structure 6 is independently disposed on a side of the isolation structure 5 away from the substrate 1, since at least part of an optical portion 61 of the optical structure 6 is located within a pixel opening K defined by the isolation structure 5, it may be possible to reduce the increase in thickness of the display panel 10 caused by adding the optical structure 6, which is conducive to reducing the thickness h1 of the display panel 10 and realizing a thinner and lighter display panel 10.

It will be noted that the “thickness h1 of the display panel 10” means a dimension h1 of the display panel 10 in a third direction Z. The following description of “the thickness h1 of the display panel 10” also follows the explanation here, and details will not be repeated.

For example, with continued reference to FIG. 8C, a surface 61b of the optical portion 61 away from the substrate 1 is farther away from the substrate 1 than the surface 5a of the isolation structure 5 away from the substrate 1. That is, a distance d5 between the surface 61b of the optical portion 61 away from the substrate 1 and the substrate 1 is greater than the distance d2 between the surface 5a of the isolation structure 5 away from the substrate 1 and the substrate 1.

That is to say, an optical portion 61 is partially located within a pixel opening K. Compared with the case where the optical structure 6 is independently disposed on the side of the isolation structure 5 away from the substrate 1, it may be possible to reduce the increase in thickness of the display panel 10 caused by adding the optical structure 6, which is conducive to reducing the thickness h1 of the display panel 10 and realizing a thinner and lighter display panel 10.

Alternatively, with continued reference to FIG. 8B, the surface 61b of the optical portion 61 away from the substrate 1 is flush with the surface 5a of the isolation structure 5 away from the substrate 1. That is, the distance d4 between the surface 61b of the optical portion 61 away from the substrate 1 and the substrate 1 is equal to the distance d2 between the surface 5a of the isolation structure 5 away from the substrate 1 and the substrate 1.

That is, an optical portion 61 is entirely located within a pixel opening K. Compared with the case where the optical structure 6 is independently disposed on the side of the isolation structure 5 away from the substrate 1, the increase in thickness of the display panel 10 caused by adding the optical structure 6 may be made 0 or close to 0, which is conducive to further reducing the thickness h1 of the display panel 10 and further realizing a thinner and lighter display panel 10.

Alternatively, with continued reference to FIG. 8A, the surface 61b of the optical portion 61 away from the substrate 1 is closer to the substrate 1 than the surface 5a of the isolation structure 5 away from the substrate 1. That is, the distance d3 between the surface 61b of the optical portion 61 away from the substrate 1 and the substrate 1 is less than the distance d2 between the surface 5a of the isolation structure 5 away from the substrate 1 and the substrate 1.

That is, an optical portion 61 is entirely located within a pixel opening K. Compared with the case where the optical structure 6 is independently disposed on the side of the isolation structure 5 away from the substrate 1, the increase in thickness of the display panel 10 caused by adding the optical structure 6 may be made 0, which is conducive to further reducing the thickness h1 of the display panel 10 and further realizing a thinner and lighter display panel 10.

For example, with continued reference to FIGS. 8A, 8B and 8C, the surface 61b of the optical portion 61 away from the substrate 1 is farther away from the substrate 1 than a surface 52a of the second sub-layer 52 of the isolation structure 5 away from the substrate 1. That is, the distance d3 between the surface 61b of the optical portion 61 away from the substrate 1 and the substrate 1 in the embodiment shown in FIG. 8A is greater than a distance d6 between the surface 52a of the second sub-layer 52 of the isolation structure 5 away from the substrate 1 and the substrate 1; the distance d4 between the surface 61b of the optical portion 61 away from the substrate 1 and the substrate 1 in the embodiment shown in FIG. 8B is greater than the distance d6 between the surface 52a of the second sub-layer 52 of the isolation structure 5 away from the substrate 1 and the substrate 1; and the distance d5 between the surface 61b of the optical portion 61 away from the substrate 1 and the substrate 1 in the embodiment shown in FIG. 8C is greater than the distance d6 between the surface 52a of the second sub-layer 52 of the isolation structure 5 away from the substrate 1 and the substrate 1.

That is to say, the optical portion 61 of the optical structure 6 is located at a position relatively far away from the substrate 1 within the pixel opening K defined by the isolation structure 5, so that there is sufficient space between the optical portion 61 and the substrate 1 for the arrangement of the light-emitting device F, and the thicknesses of all film layers (such as the first electrode 41, the light-emitting portion 43 and the second electrode 42) in the light-emitting device F may be guaranteed, which is conducive to improving the optical performance of the light-emitting device F.

For example, a material of the optical portion 61 of the optical structure 6 may include photoresist.

For example, with continued reference to FIGS. 8A, 8B and 8C, the thickness h2 of the optical portion 61 is greater than or equal to 1.5 μm.

For example, the thickness h2 of the optical portion 61 may be 1.5 μm, 1.8 μm, 2.1 μm, 2.3 μm, 2.5 μm, 2.6 μm, 2.8 μm, 3 μm, 3.3 μm, or 3.6 μm.

In some embodiments, with continued reference to FIGS. 8A, 8B, and 8C, the optical structure 6 may be located between the first inorganic encapsulation layer 81 and the organic encapsulation layer 83. The plurality of optical portions 61 in the optical structure 6 may be located between the first inorganic encapsulation layer 81 and the organic encapsulation layer 83. That is, the first inorganic encapsulation layer 81 in the encapsulation structure 8 is located between the plurality of optical portions 61 in the optical structure 6 and the light-emitting devices F, and the organic encapsulation layer 83 and the second inorganic encapsulation layer 82 in the encapsulation structure 8 are located on a side of the plurality of optical portions 61 in the optical structure 6 away from the substrate.

Since the first inorganic encapsulation layer 81 in the encapsulation structure 8 is located between the plurality of optical portions 61 in the optical structure 6 and the light-emitting devices F and the organic encapsulation layer 83 and the second inorganic encapsulation layer 82 in the encapsulation structure 8 are located on the side of the plurality of optical portions 61 in the optical structure 6 away from the substrate, compared with the case where the organic encapsulation layer 83 and the second inorganic encapsulation layer 82 in the encapsulation structure 8 are also located between the plurality of optical portions 61 in the optical structure 6 and the light-emitting devices F, a distance between the optical portion 61 and the light-emitting device F may be reduced, which is beneficial for the plurality of optical portions 61 in the optical structure 6 to better function and in turn improves the optical performance of the display panel 10.

Next, the implementation manner of using the optical structure 6 to form the enhanced efficiency structure (EES) and the principle of improving the light extraction efficiency of the display panel 10 will be described in detail.

In some embodiments, with continued reference to FIG. 5, light emitted by the light-emitting device F finally exits from the cover plate 20 to the air; a refractive index n1 of the cover plate 20 is greater than a refractive index n0 of the air. That is, the refractive index of the cover plate 20 is relatively high, and the refractive index of the air is relatively low. In the case where the display panel 10 is not provided with the optical structure 6 for forming the enhanced efficiency structure (EES), when the light emitted by the light-emitting device F exits from the cover plate 20 of a high refractive index to the air of a low refractive index, if an incident angle of the light at the interface between the cover plate 20 and the air reaches or exceeds the critical angle of total reflection arcsin(n0/n1), the total reflection will occur (for example, the light path L1 in FIG. 5), resulting in a low overall light extraction efficiency of the display panel 10.

It will be noted that the “total reflection” is an optical phenomenon, which means that when light travels from a medium of a higher refractive index to a medium of a lower refractive index (for example, the light travels from the cover plate 20 of a high refractive index to the air of a low refractive index), if the incident angle reaches or exceeds the critical angle of total reflection, no refracted light will appear, and the incident light will be reflected without entering the medium of a low refractive index (e.g. the air).

Based on this, in some embodiments, with continued reference to FIGS. 8A, 8B and 8C, in the case where the display panel 10 includes the optical structure 6 and the optical structure 6 is used for forming the enhanced efficiency structure (EES), a refractive index n2 of the optical portion 61 of the optical structure 6 is different from a refractive index n3 of the third sub-layer 53 of the isolation structure 5. That is, a refractive index of one of the optical portion 61 of the optical structure 6 and the third sub-layer 53 of the isolation structure 5 is relatively high, and a refractive index of another of the optical portion 61 of the optical structure 6 and the third sub-layer 53 of the isolation structure 5 is relatively low.

Since the refractive index of one of the optical portion 61 of the optical structure 6 and the third sub-layer 53 of the isolation structure 5 is relatively high and the refractive index of another of the optical portion 61 of the optical structure 6 and the third sub-layer 53 of the isolation structure 5 is relatively low, the optical portions 61 of the optical structure 6 and the third sub-layer 53 of the isolation structure 5 can constitute a structure of alternating high and low refractive indexes, which may refract or scatter light emitted by the light-emitting devices F, change the propagation direction of the light, and reduce light that is totally reflected at the interface between the cover plate 20 and the air. In other words, the light that was originally totally reflected in the display panel 10 is emitted, so that more light may be transmitted to the air through the cover plate 20, and the light transmittance of the display panel 10 is increased. As a result, the light extraction efficiency of the display panel 10 is effectively improved.

For example, the refractive index n2 of the optical portion 61 of the optical structure 6 may be greater than the refractive index n3 of the third sub-layer 53 of the isolation structure 5. For example, the refractive index of the optical portion 61 of the optical structure 6 may be greater than 1.65, and the refractive index of the third sub-layer 53 of the isolation structure 5 may be less than 1.4.

Alternatively, the refractive index n3 of the third sub-layer 53 of the isolation structure 5 may be greater than the refractive index n2 of the optical portion 61 of the optical structure 6. For example, the refractive index of the third sub-layer 53 of the isolation structure 5 may be greater than 1.65, and the refractive index of the optical portion 61 of the optical structure 6 may be less than 1.4.

In some embodiments, the material of the optical portion 61 of the optical structure 6 may include first particles. A refractive index of the first particles is in a range of 1 to 2. The overall refractive index of the optical portion 61 of the optical structure 6 may be adjusted by providing first particles of different refractive indexes in the optical portion 61 of the optical structure 6, so that the refractive index n2 of the optical portion 61 of the optical structure 6 is greater than or less than the refractive index n3 of the third sub-layer 53 of the isolation structure 5, and a difference between the refractive index n2 of the optical portion 61 of the optical structure 6 and the refractive index n3 of the third sub-layer 53 of the isolation structure 5 can be adjusted according to actual needs, which is conducive to improving the optical performance of the display panel 10.

For example, the first particles may include hollow particles, such as hollow zirconium oxide particles or hollow silicon oxide particles.

For example, the refractive index of the first particles may be 1, 1.1, 1.2, 1.3, 1.4, 1.5, 1.6, 1.7, 1.8, 1.9, or 2.

In some embodiments, with continued reference to FIGS. 8A, 8B and 8C, the first inorganic encapsulation layer 81 of the encapsulation structure 8 is disposed between the optical portions 61 of the optical structure 6 and the third sub-layer 53 of the isolation structure 5. The refractive index n2 of the optical portion 61 of the optical structure 6, the refractive index n3 of the third sub-layer 53 of the isolation structure 5, and a refractive index n4 of the first inorganic encapsulation layer 81 of the encapsulation structure 8 are all different.

The refractive index n2 of the optical portion 61 of the optical structure 6 and the refractive index n3 of the third sub-layer 53 of the isolation structure 5 may both be greater than the refractive index n4 of the first inorganic encapsulation layer 81 of the encapsulation structure 8. That is, the refractive index of the optical portion 61 of the optical structure 6 and the refractive index of the third sub-layer 53 of the isolation structure 5 are relatively high, and the refractive index of the first inorganic encapsulation layer 81 of the encapsulation structure 8 is relatively low. The optical portion 61 of the optical structure 6, the first inorganic encapsulation layer 81 of the encapsulation structure 8 and the third sub-layer 53 of the isolation structure 5 may constitute a structure of high-low-high refractive index, which may refract or scatter the light emitted by the light-emitting device F, change the propagation direction of the light, and reduce the light that is totally reflected at the interface between the cover plate 20 and the air. In other words, the light that was originally totally reflected in the display panel 10 is emitted, so that more light may be transmitted to the air through the cover plate 20, and the light transmittance of the display panel 10 is further increased. As a result, the light extraction efficiency of the display panel 10 is effectively improved.

Alternatively, the refractive index n2 of the optical portion 61 of the optical structure 6 and the refractive index n3 of the third sub-layer 53 of the isolation structure 5 may both be less than the refractive index n4 of the first inorganic encapsulation layer 81 of the encapsulation structure 8. That is, the refractive index of the optical portion 61 of the optical structure 6 and the refractive index of the third sub-layer 53 of the isolation structure 5 are relatively low, and the refractive index of the first inorganic encapsulation layer 81 of the encapsulation structure 8 is relatively high. The optical portion 61 of the optical structure 6, the first inorganic encapsulation layer 81 of the encapsulation structure 8 and the third sub-layer 53 of the isolation structure 5 may constitute a structure of low-high-low refractive index, which may refract or scatter the light emitted by the light-emitting device F, change the propagation direction of the light, and reduce the light that is totally reflected at the interface between the cover plate 20 and the air. In other words, the light that was originally totally reflected in the display panel 10 is emitted, so that more light may be transmitted to the air through the cover plate 20, and the light transmittance of the display panel 10 is further increased. As a result, the light extraction efficiency of the display panel 10 is effectively improved.

Next, the implementation manner of using the optical structure 6 to form the color filter on encapsulation (COE) structure and the principle of improving light transmittance will be described in detail.

The color filter on encapsulation (COE), also known as the polarizer-less (POL-Less) structure, means a structure in which a polarizer in the display panel 10 is replaced by a color film or a color filter (CF), which has the advantages such as improving the light transmittance of the display panel 10, reducing the operating power consumption of the display panel 10, and making the display panel 10 thinner and lighter.

In some embodiments, as shown in FIG. 9, FIG. 9 is a structural diagram of a display panel 10 according to some embodiments. In the case where the optical structure 6 is used for forming the color filter on encapsulation (COE) structure, the optical portion 61 of the optical structure 6 is a filter color resist 611. For the light-emitting device F and the filter color resist 611 that are located in the same pixel opening K, a color of light transmitted by the filter color resist 611 is the same as a color of light emitted by the light-emitting device F. That is to say, the color of light transmitted by the filter color resist 611 located in the same pixel opening K as the first color light-emitting device F1 is the first color (e.g., red), the color of light transmitted by the filter color resist 611 located in the same pixel opening K as the second color light-emitting device F2 is the second color (e.g., green), and the color of light transmitted by the filter color resist 611 located in the same pixel opening K as the third color light-emitting device F3 is the third color (e.g., blue).

The filter color resist 611 is arranged corresponding to the light-emitting device F, and is located on the light exit side of the light-emitting device F, which may reduce the reflection probability of ambient light in a region where the light-emitting device F is located (i.e., a light-emitting region).

With continued reference to FIG. 9, the optical portion 61 of the optical structure 6 is the filter color resist 611, and at least the third sub-layer 53 of the isolation structure 5 includes a light-shielding material. When the ambient light is incident onto the third sub-layer 53, the third sub-layer 53 may absorb the ambient light, thereby avoiding the reflection of the ambient light and reducing the reflection probability of the ambient light in a region where the isolation structure 5 is located (i.e., a non-light-emitting region).

In summary, since the filter color resist 611 is arranged on the light exit side of the light-emitting device F and at least the third sub-layer 53 of the isolation structure 5 includes a light-shielding material, it may be possible to reduce the overall reflection probability of the ambient light, and in turn improve the contrast of the display panel 10.

In this way, without the polarizer, the display panel 10 may still realize a good anti-reflection effect. In addition, since the polarizer is removed, the light transmittance of the display panel 10 may be improved, which may effectively reduce the power consumption of the display panel 10 and make the display panel 10 thinner and lighter.

For example, the third sub-layer 53 of the isolation structure 5 may include a light-shielding material; or, each of the second sub-layer 52 and the third sub-layer 53 of the isolation structure 5 may include a light-shielding material.

It will be noted that, in the embodiment shown in FIG. 9 in which the optical structure 6 is used for forming the color filter on encapsulation (COE) structure, the surface 61b of the optical portion 61 (i.e., the filter color resist 611) away from the substrate 1 being closer to the substrate 1 than the surface 5a of the isolation structure 5 away from the substrate 1 is taken as an example for illustration. However, in the embodiment shown in FIG. 9 in which the optical structure 6 is used for forming the color filter on encapsulation (COE) structure, the arrangement of the optical portion 61 (i.e., the filter color resist 611) and the isolation structure 5 is not limited thereto. For example, the surface 61b of the optical portion 61 (i.e., the filter color resist 611) away from the substrate 1 may be farther away from the substrate 1 than the surface 5a of the isolation structure 5 away from the substrate 1. For another example, the surface 61b of the optical portion 61 (i.e., the filter color resist 611) away from the substrate 1 may be flush with the surface 5a of the isolation structure 5 away from the substrate 1. Details will not be repeated here.

For example, a material of the filter color resist 611 may include one or more of oxazine compounds, anthocyanin compounds, tetrazophene-based squaric acid compounds, and the like.

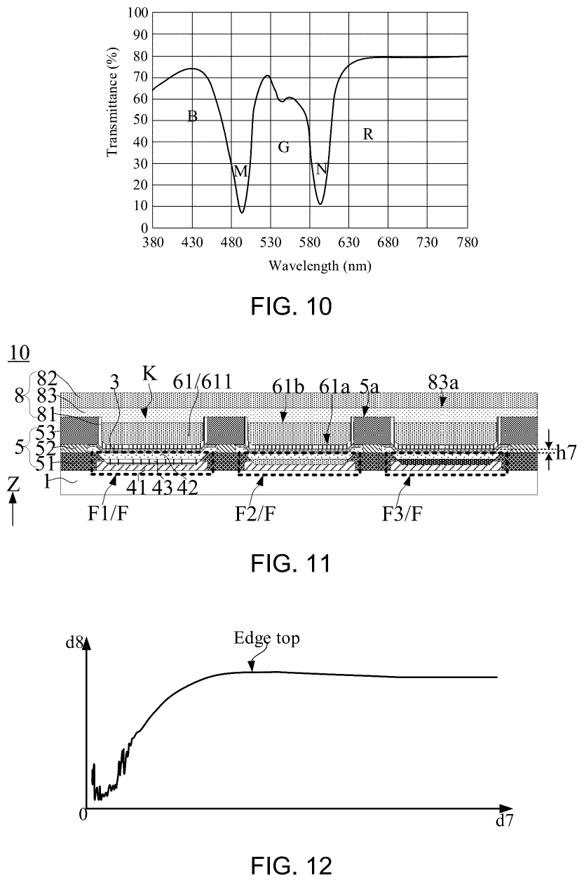

In some embodiments, as shown in FIG. 10, FIG. 10 is a schematic diagram showing a transmittance curve of an optical portion 61 (i.e., a filter color resist 611) of an optical structure 6 in a display panel 10 for light of different bands, in accordance with some embodiments. Light transmittance of the red light band (R), light transmittance of the green light band (G) and light transmittance of the blue light band (B) are all greater than 70%. However, light transmittance of a first transition band N between the red light band (R) and the green light band (G) is not 0, and light transmittance of a second transition band M between the green light band (G) and the blue light band (B) is not 0, which easily leads to a decrease in color purity of an image displayed by the display panel 10.

In light of this, in some embodiments, as shown in FIG. 11, FIG. 11 is a structural diagram of a display panel 10 according to some embodiments. The display panel 10 further includes an anti-reflection layer 3. The anti-reflection layer 3 is located between the first inorganic encapsulation layer 81 of the encapsulation structure 8 and the second electrodes 42 of the light-emitting devices F.

The anti-reflection layer 3 is provided between the first inorganic encapsulation layer 81 of the encapsulation structure 8 and the second electrode 42 of the light-emitting device F, the anti-reflection layer 3 and a film layer adjacent to the anti-reflection layer 3 (for example, the first inorganic encapsulation layer 81 of the encapsulation structure 8) constitute a stacked structure, and the anti-reflection layer 3 and the film layer adjacent to the anti-reflection layer 3 (for example, the first inorganic encapsulation layer 81 of the encapsulation structure 8) have different refractive indexes. Therefore, a microcavity structure is formed between the first electrode 41 (i.e., the reflective electrode) and the stacked structure. The light emitted by the light-emitting portion 43 of the light-emitting device F passes through the second electrode 42 and the stacked structure in sequence and exits from the display panel 10. The microcavity structure may enhance the light in a specific band (for example, the red light band (R), the green light band (G), and the blue light band (B)), which increases the light extraction amount in the specific band (for example, the red light band (R), the green light band (G), and the blue light band (B)); and the microcavity structure weakens the light in other bands (for example, the first transition band N between the red light band (R) and the green light band (G), and the second transition band M between the green light band (G) and the blue light band (B)), which reduces the light extraction amount in other bands (for example, the first transition band N between the red light band (R) and the green light band (G), and the second transition band M between the green light band (G) and the blue light band (B)). Therefore, the display effect of the display panel 10 is improved.

For example, a material of the anti-reflection layer 3 may include metal or metal compounds, e.g., thick reflective metal (M-O-M) or thick reflective metal (M-I-M), where “M” may be Sm/Alq3/Al, Sm/Alq3/Sm/Alq3/Al or Al/CuPc/Al/CuPc/Al; “O” may be iF/Cr/LiF/Cr/LiF/Ag, ZnO, Alq3+C60, Alq3, CuPc or LiF; and “I” may be iF/Cr/LiF/Cr/LiF/Ag, ZnO, Alq3+C60, Alq3, CuPc, or LiF.

For example, with continued reference to FIG. 11, a thickness h7 of the anti-reflection layer 3 may be in a range of 1 nm to 50 nm.

For example, the thickness h7 of the anti-reflection layer 3 may be 1 nm, 5 nm, 8 nm, 10 nm, 12 nm, 15 nm, 18 nm, 20 nm, 23 nm, 25 nm, 28 nm, 30 nm, 33 nm, 35 nm, 38 nm, 40 nm, 43 nm, 45 nm, 48 nm, or 50 nm.

It will be noted that the “thickness h7 of the anti-reflection layer 3” means the dimension h7 of the anti-reflection layer 3 in the third direction Z.

The organic encapsulation layer 83 of the encapsulation structure 8 will be described in detail below.

In some embodiments, the organic encapsulation layer 83 of the encapsulation structure 8 may be formed by an inkjet printing (IJP) process.

The detailed steps may be as follows. The material used for forming the organic encapsulation layer 83 of the encapsulation structure 8 is dissolved in a solvent to form a printing ink. The printing ink is dropped onto a side of the first inorganic encapsulation layer 81 of the encapsulation structure 8 away from the substrate 1 through an inkjet printer. The liquid printing ink is freely leveled on the side of the first inorganic encapsulation layer 81 away from the substrate 1, and then is cured with ultraviolet light to form a uniform film layer (i.e., the organic encapsulation layer 83 of the encapsulation structure 8). However, when the printing ink is dropped onto the side of the first inorganic encapsulation layer 81 of the encapsulation structure 8, the flow speed of droplets at an edge of the display panel 10 is different from the flow speed of droplets at a center of the display panel 10, and a surface of the formed organic encapsulation layer 83 away from the substrate 1 is uneven due to the surface tension of droplets. For example, an edge of the surface of the organic encapsulation layer 83 away from the substrate 1 is prone to protrusion (i.e., Edge Top defects).

As shown in FIG. 12, FIG. 12 is a schematic diagram showing a thickness variation trend of an organic encapsulation layer 83 of an encapsulation structure 8 in a direction from an edge to a center of a display panel 10. In FIG. 12, the abscissa d7 represents a distance from the edge of the display panel 10, and the ordinate d8 represents a distance between the surface of the organic encapsulation layer 83 of the encapsulation structure 8 away from the substrate 1 and the substrate 1. An edge of the surface of the organic encapsulation layer 83 of the encapsulation structure 8 away from the substrate 1 has a protrusion (i.e., Edge Top) higher than other parts. The Edge Top defect causes the uneven surface of the organic encapsulation layer 83 away from the substrate 1, which easily leads to difference in light extraction efficiency at different portions of the display panel 10, thus affecting the optical uniformity of the display panel 10.

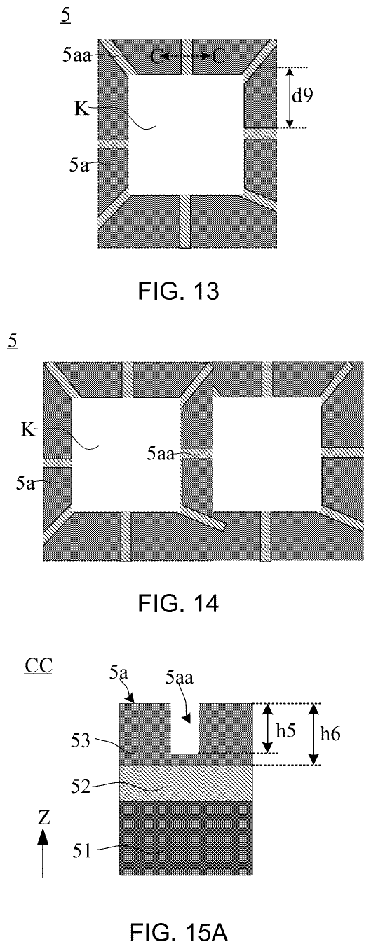

In light of this, in some embodiments, as shown in FIG. 13 and with reference to FIGS. 8A, 8B, 8C and 9, FIG. 13 is a plan view showing a partial structure of an isolation structure 5 according to some embodiments. The surface 5a of the isolation structure 5 away from the substrate 1 is provided with a plurality of grooves 5aa.

It will be understood that the surface 5a of the isolation structure 5 away from the substrate 1 and a surface of the third sub-layer 53 of the isolation structure 5 away from the substrate 1 are the same surface.

The surface 5a of the isolation structure 5 away from the substrate 1 is provided with the plurality of grooves 5aa, which may play a guiding role for the printing ink used for forming the organic encapsulation layer 83 of the encapsulation structure 8, which is conducive to facilitating the leveling of the printing ink, improving the flatness of the surface 83a of the organic encapsulation layer 83 away from the substrate 1, reducing the difference in light extraction efficiency at different portions of the display panel 10, and improving the optical uniformity of the display panel 10.

It will be noted that the embodiment shown in FIG. 13 and the following embodiments are merely illustrated by taking the pixel opening K of a rectangular structure as an example, but the embodiments of the present disclosure include but are not limited to this, and the shape of the pixel opening K may also adopt any other shape.

In some examples, with continued reference to FIG. 5, one light-emitting device F is located in one pixel opening K.

Alternatively, with continued reference to FIG. 8A, the display panel 10 includes the optical structure 6, one optical portion 61 of the plurality of optical portions 61 of the optical structure 6 is located in one pixel opening K, and the surface 61b of the optical portion 61 away from the substrate 1 is closer to the substrate 1 than the surface 5a of the isolation structure 5 away from the substrate 1. That is, the distance d3 between the surface 61b of the optical portion 61 away from the substrate 1 and the substrate 1 is less than the distance d2 between the surface 5a of the isolation structure 5 away from the substrate 1 and the substrate 1.

A thickness h3 of a portion of the organic encapsulation layer 83 of the encapsulation structure 8 corresponding to the pixel opening K is greater than a thickness h4 of a portion of the organic encapsulation layer 83 corresponding to the isolation structure 5. That is, there is a difference between the thickness h3 of the portion of the organic encapsulation layer 83 of the encapsulation structure 8 corresponding to the pixel opening K and the thickness h4 of the portion of the organic encapsulation layer 83 corresponding to the isolation structure 5, which easily leads to a difference between a light extraction efficiency of a region corresponding to the pixel opening K of the display panel 10 and a light extraction efficiency of a region corresponding to the isolation structure 5, and in turn affects the optical uniformity of the display panel 10.

It will be noted that the “thickness h3 of the portion of the organic encapsulation layer 83 of the encapsulation structure 8 corresponding to the pixel opening K” means a straight-line distance between a portion, corresponding to the pixel opening K, of the surface 83a, away from the substrate 1, of the organic encapsulation layer 83 of the encapsulation structure 8 and a surface 83b, close to the substrate 1, of the organic encapsulation layer 83 of the encapsulation structure 8.

The “thickness h4 of the portion of the organic encapsulation layer 83 of the encapsulation structure 8 corresponding to the isolation structure 5” means a straight-line distance between a portion, corresponding to the isolation structure 5, of the surface 83a, away from the substrate 1, of the organic encapsulation layer 83 of the encapsulation structure 8 and the surface 83b, close to the substrate 1, of the organic encapsulation layer 83 of the encapsulation structure 8.

The following descriptions of “thickness h3 of the portion of the organic encapsulation layer 83 of the encapsulation structure 8 corresponding to the pixel opening K” and “thickness h4 of the portion of the organic encapsulation layer 83 of the encapsulation structure 8 corresponding to the isolation structure 5” also follows these explanations, and details will not be repeated.

On this basis, in some embodiments, with continued reference to FIG. 13 and with reference to FIG. 14, FIG. 14 is a plan view showing a partial structure of an isolation structure 5 according to some embodiments. The groove 5aa is communicated with at least one pixel opening K.

Since the surface 5a of the isolation structure 5 away from the substrate 1 is provided with the plurality of grooves 5aa and the groove 5aa is communicated with at least one pixel opening K, the thickness h4 of the portion of the organic encapsulation layer 83 of the encapsulation structure 8 corresponding to the isolation structure 5 may be increased, and the difference between the thickness h3 of the portion of the organic encapsulation layer 83 of the encapsulation structure 8 corresponding to the pixel opening K and the thickness h4 of the portion of the organic encapsulation layer 83 corresponding to the isolation structure 5 may be reduced. Thus, the light extraction efficiency of the region corresponding to the pixel opening K of the display panel 10 and the light extraction efficiency of the region corresponding to the isolation structure 5 are balanced, and the optical uniformity of the display panel 10 is further improved.

In addition, since the groove 5aa is communicated with at least one pixel opening K, a part of the printing ink for forming the organic encapsulation layer 83 of the encapsulation structure 8 that is located in the pixel opening K may flow to other regions through the groove 5aa, which avoids the accumulation of the printing ink for forming the organic encapsulation layer 83 of the encapsulation structure 8 in the pixel opening K, which is conducive to facilitating the leveling of the printing ink for forming the organic encapsulation layer 83 of the encapsulation structure 8, improving the flatness of the surface 83a of the organic encapsulation layer 83 of the encapsulation structure 8 away from the substrate 1, and improving the optical uniformity of the display panel 10.

For example, with continued reference to FIG. 13, the groove 5aa may be communicated with one pixel opening K.

Alternatively, with continued reference to FIG. 14, at least one groove 5aa is disposed between two adjacent pixel openings K among the plurality of pixel openings K defined by the isolation structure 5, and the groove(s) 5aa are communicated with each of the two adjacent pixel openings K.

It will be noted that, in the embodiment shown in FIG. 14, light-emitting portions 43 of the light-emitting devices F located in the two adjacent pixel openings K that are communicated via the groove(s) 5aa are not connected.

In some embodiments, with continued reference to FIG. 13, one pixel opening K is communicated with multiple grooves 5aa, the multiple grooves 5aa each extend in a direction away from the pixel opening K, and the multiple grooves 5aa are arranged around the pixel opening K and arranged at intervals.

Since one pixel opening K is communicated with multiple grooves 5aa and each groove 5aa extends in the direction away from the pixel opening K, the part of the printing ink for forming the organic encapsulation layer 83 of the encapsulation structure 8 that is located in the pixel opening K may flow to other regions through the groove 5aa, which avoids the accumulation of the printing ink for forming the organic encapsulation layer 83 of the encapsulation structure 8 in the pixel opening K, which is conducive to facilitating the leveling of the printing ink for forming the organic encapsulation layer 83 of the encapsulation structure 8, improving the flatness of the surface 83a of the organic encapsulation layer 83 of the encapsulation structure 8 away from the substrate 1, and improving the optical uniformity of the display panel 10.

For example, with continued reference to FIG. 13, along a direction in which the multiple grooves 5aa surround the pixel opening K, a distance d9 between two adjacent grooves 5aa is equal.

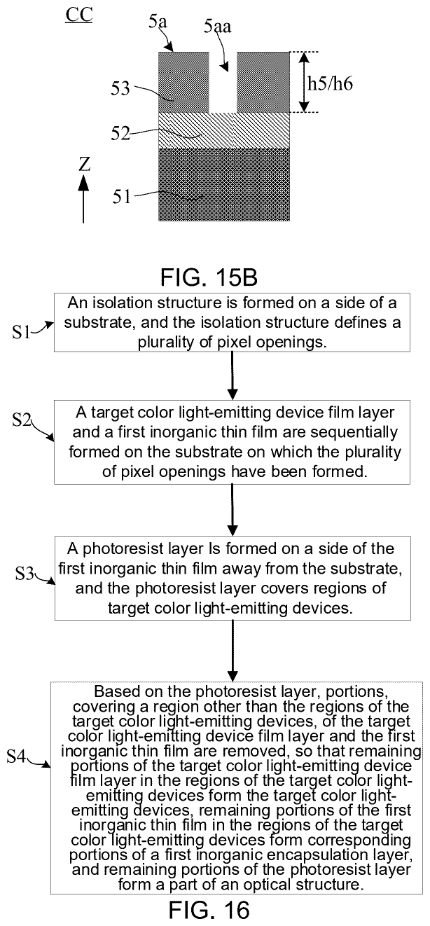

In some embodiments, as shown in FIGS. 15A and 15B, FIG. 15A is a sectional view of the isolation structure 5 in FIG. 13 taken along the line C-C, and FIG. 15B is another sectional view of the isolation structure 5 in FIG. 13 taken along the line C-C. A depth h5 of the groove 5aa is less than or equal to a thickness h6 of the third sub-layer 53 of the isolation structure 5.

It will be noted that the “depth h5 of the groove 5aa” means the dimension h5 of the groove 5aa in the third direction Z. The “thickness h6 of the third sub-layer 53 of the isolation structure 5” means the dimension h6 of the third sub-layer 53 of the isolation structure 5 in the third direction Z. The following descriptions of “depth h5 of the groove 5aa” and “thickness h6 of the third sub-layer 53 of the isolation structure 5” also follow these explanations, and details will not be repeated here.

For example, with continued reference to FIG. 15A, the depth h5 of the groove 5aa may be less than the thickness h6 of the third sub-layer 53 of the isolation structure 5. That is, the groove 5aa does not penetrate the third sub-layer 53 of the isolation structure 5.

Alternatively, with continued reference to FIG. 15B, the depth h5 of the groove 5aa may be equal to the thickness h6 of the third sub-layer 53 of the isolation structure 5. That is, the groove 5aa penetrates the third sub-layer 53 of the isolation structure 5 and is in contact with the second sub-layer 52 of the isolation structure 5.

In some embodiments, a material of the third sub-layer 53 of the isolation structure 5 includes a hydrophobic material or an oleophobic material, and a material of the optical structure 6 includes a hydrophobic material or an oleophobic material. The material of the third sub-layer 53 of the isolation structure 5 includes a hydrophobic material or an oleophobic material, and the material of the optical portion 61 of the optical structure 6 includes a hydrophobic material or an oleophobic material.

For example, the material of the third sub-layer 53 of the isolation structure 5 includes a hydrophobic material, and the material of the optical portion 61 of the optical structure 6 includes a hydrophobic material. Alternatively, the material of the third sub-layer 53 of the isolation structure 5 includes an oleophobic material, and the material of the optical portion 61 of the optical structure 6 includes an oleophobic material.

The printing ink used in the inkjet printing (IJP) process is usually formed by dissolving an organic material in a lipid or alcohol solvent, and has both water-based and oil-based properties. Based on the water-based property of the printing ink, when the material of the third sub-layer 53 of the isolation structure 5 and the material of the optical portion 61 of the optical structure 6 may both include oleophobic materials, the printing ink may have small contact angles on sides, away from the substrate 1, of the third sub-layer 53 of the isolation structure 5 and the optical portion 61 of the optical structure 6, which facilitates leveling, which is conducive to improving the flatness of the formed organic encapsulation layer 83 and the uniformity of the film thickness.

Based on the oil-based property of the printing ink, when the material of the third sub-layer 53 of the isolation structure 5 and the material of the optical portion 61 of the optical structure 6 may both include hydrophobic materials, the printing ink may have small contact angles on sides, away from the substrate 1, of the third sub-layer 53 of the isolation structure 5 and the optical portion 61 of the optical structure 6, which facilitates leveling, which is conducive to improving the flatness of the formed organic encapsulation layer 83 and the uniformity of the film thickness.

Next, a method for manufacturing a display panel 10 will be described in detail.

In some embodiments, as shown in FIG. 16, FIG. 16 is a flow diagram of a method for manufacturing a display panel 10 according to some embodiments. The method for manufacturing the display panel 10 includes steps S1 to S4.

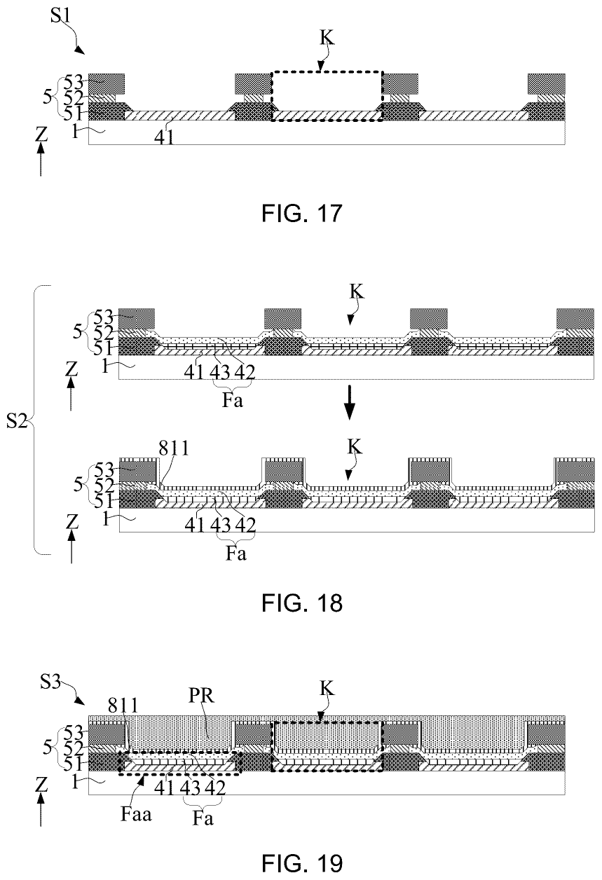

In S1, as shown in FIG. 17 which is a diagram showing a structure corresponding to the step S1 of the method for manufacturing the display panel 10 according to the embodiment shown in FIG. 16, an isolation structure 5 is formed on a side of a substrate 1. The isolation structure 5 defines a plurality of pixel openings K.

In S2, as shown in FIG. 18 which is a diagram showing a structure corresponding to the step S2 of the method for manufacturing the display panel 10 according to the embodiment shown in FIG. 16, a target color light-emitting device film layer Fa and a first inorganic thin film 811 are sequentially formed on the substrate 1 on which the plurality of pixel openings K have been formed.

In S3, as shown in FIG. 19 which is a diagram showing a structure corresponding to the step S3 of the method for manufacturing the display panel 10 according to the embodiment shown in FIG. 16, a photoresist layer PR is formed on a side of the first inorganic thin film 811 away from the substrate 1, and the photoresist layer PR covers regions of target color light-emitting devices Faa.

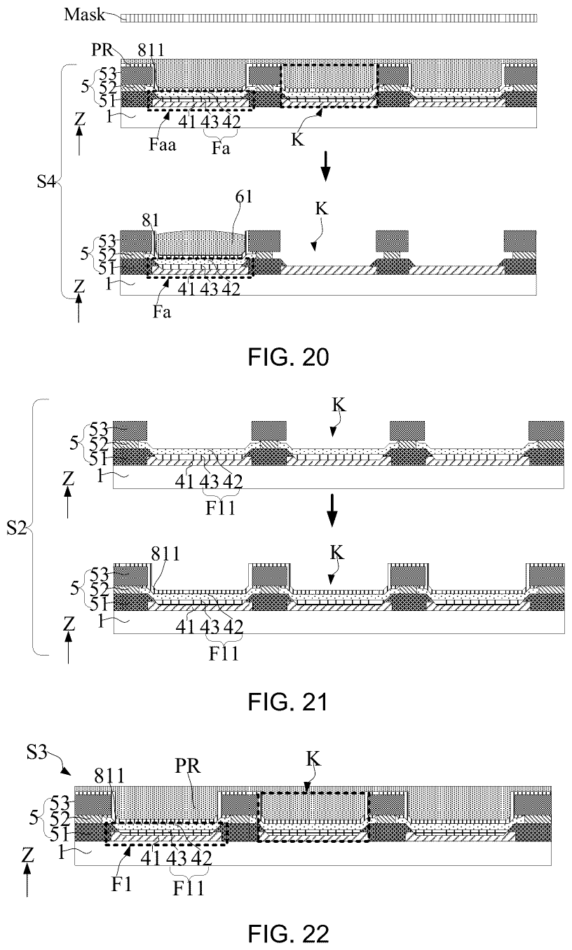

In S4, as shown in FIG. 20 which is a diagram showing a structure corresponding to the step S4 of the method for manufacturing the display panel 10 according to the embodiment shown in FIG. 16, portions, covering a region other than the regions of the target color light-emitting devices Faa, of the target color light-emitting device film layer Fa and the first inorganic thin film 811 are removed based on the photoresist layer PR, so that remaining portions of the target color light-emitting device film layer Fa in the regions of the target color light-emitting devices Faa form the target color light-emitting devices Faa, remaining portions of the first inorganic thin film 811 in the regions of the target color light-emitting devices Faa form corresponding portions of a first inorganic encapsulation layer 81, and remaining portions of the photoresist layer PR form a part of an optical structure 6. For example, the remaining portions of the photoresist layer PR form optical portions 61 of the optical structure 6.

Optionally, the photoresist layer PR may include positive photoresist or negative photoresist.

It will be noted that a portion of the positive photoresist that is exposed to light (i.e. an exposed portion) will dissolve in a photoresist developing solution, and a portion of the positive photoresist that is not exposed to light (i.e. a portion other than the exposed portion) will not dissolve in the photoresist developing solution or will dissolve in the photoresist developing solution very slowly.

A portion of the negative photoresist that is exposed to light (i.e. an exposed portion) will not dissolve in a photoresist developing solution or will dissolve in the photoresist developing solution very slowly, and a portion of the negative photoresist that is not exposed to light (i.e. a portion other than the exposed portion) will dissolve in the photoresist developing solution.

With continued reference to FIG. 20, the photoresist layer PR may be exposed using a mask and then subjected to a development reaction, the portions, covering the region other than the regions of the target color light-emitting devices Faa, of the target color light-emitting device film layer Fa and the first inorganic thin film 811 are removed, so that the remaining portions of the target color light-emitting device film layer Fa in the regions of the target color light-emitting devices Faa form the target color light-emitting devices Faa, the remaining portions of the first inorganic thin film 811 in the regions of the target color light-emitting devices Faa form the corresponding portions of the first inorganic encapsulation layer 81, and the remaining portions of the photoresist layer PR form a part of the optical structure 6.

It will be understood that, in the case where the photoresist layer PR includes the positive photoresist, a portion of the photoresist layer PR in the region other than the regions of the target color light-emitting devices Faa is an exposed portion, and portions of the photoresist layer PR in the regions of the target color light-emitting devices Faa are portions other than the exposed portion.

In the case where the photoresist layer PR includes the negative photoresist, portions of the photoresist layer PR in the regions of the target color light-emitting devices Faa are exposed portions, and a portion of the photoresist layer PR in the region other than the regions of the target color light-emitting devices Faa is a portion other than the exposed portions.

Since the optical portion 61 of the optical structure 6 includes photoresist, through the above steps, the optical structure 6 (i.e., the optical portions 61 of the optical structure 6) may be formed at the same time when the target color light-emitting devices Faa and the corresponding portions of the first inorganic encapsulation layer 81 are formed. Neither additional mask (Mask) nor additional operating step(s) are needed, and it is conducive to reducing the cost of manufacturing the display panel 10 and simplifying the steps of manufacturing the display panel 10.

For example, the “target color light-emitting devices Faa” may be the first color light-emitting devices F1, the second color light-emitting devices F2, or the third color light-emitting devices F3.

For example, the first color light-emitting devices F1, portions of the first inorganic encapsulation layer 81 corresponding to the first color light-emitting devices F1 and optical portions 61 corresponding to the first color light-emitting devices F1 may be firstly formed; then, the second color light-emitting devices F2, portions of the first inorganic encapsulation layer 81 corresponding to the second color light-emitting devices F2 and optical portions 61 corresponding to the second color light-emitting devices F2 may be formed; next, the third color light-emitting devices F3, portions of the first inorganic encapsulation layer 81 corresponding to the third color light-emitting devices F3 and optical portions 61 corresponding to the third color light-emitting devices F3 may be formed.

Alternatively, the second color light-emitting devices F2, portions of the first inorganic encapsulation layer 81 corresponding to the second color light-emitting devices F2 and optical portions 61 corresponding to the second color light-emitting devices F2 may be firstly formed; then, the first color light-emitting devices F1, portions of the first inorganic encapsulation layer 81 corresponding to the first color light-emitting devices F1 and optical portions 61 corresponding to the first color light-emitting devices F1 may be formed; next, the third color light-emitting devices F3, portions of the first inorganic encapsulation layer 81 corresponding to the third color light-emitting devices F3 and optical portions 61 corresponding to the third color light-emitting devices F3 may be formed.

Alternatively, the third color light-emitting devices F3, portions of the first inorganic encapsulation layer 81 corresponding to the third color light-emitting devices F3 and optical portions 61 corresponding to the third color light-emitting devices F3 may be firstly formed; then, the first color light-emitting devices F1, portions of the first inorganic encapsulation layer 81 corresponding to the first color light-emitting devices F1 and optical portions 61 corresponding to the first color light-emitting devices F1 may be formed; next, the second color light-emitting devices F2, portions of the first inorganic encapsulation layer 81 corresponding to the second color light-emitting devices F2 and optical portions 61 corresponding to the second color light-emitting devices F2 may be formed.

Some embodiments of the present disclosure are schematically described below by taking an example in which the first color light-emitting devices F1, portions of the first inorganic encapsulation layer 81 corresponding to the first color light-emitting devices F1 and optical portions 61 corresponding to the first color light-emitting devices F1 may be firstly formed, then the second color light-emitting devices F2, portions of the first inorganic encapsulation layer 81 corresponding to the second color light-emitting devices F2 and optical portions 61 corresponding to the second color light-emitting devices F2 may be formed, and then the third color light-emitting devices F3, portions of the first inorganic encapsulation layer 81 corresponding to the third color light-emitting devices F3 and optical portions 61 corresponding to the third color light-emitting devices F3 may be formed.

With continued reference to FIG. 16, in the case where the target color light-emitting devices Faa are the first color light-emitting devices F1, forming the first color light-emitting devices F1, the portions of the first inorganic encapsulation layer 81 corresponding to the first color light-emitting devices F1, and the optical portions 61 corresponding to the first color light-emitting devices F1 includes the following steps.

In S2, as shown in FIG. 21 which is a diagram showing a structure corresponding to the step S2 of the method for manufacturing the display panel 10 according to the embodiment shown in FIG. 16, a first color light-emitting device film layer F11 and the first inorganic thin film 811 are sequentially formed on the substrate 1 on which the plurality of pixel openings K have been formed.

In S3, as shown in FIG. 22 which is a diagram showing a structure corresponding to the step S3 of the method for manufacturing the display panel 10 according to the embodiment shown in FIG. 16, the photoresist layer PR is formed on the side of the first inorganic thin film 811 away from the substrate 1, and the photoresist layer PR covers regions of first color light-emitting devices F1.

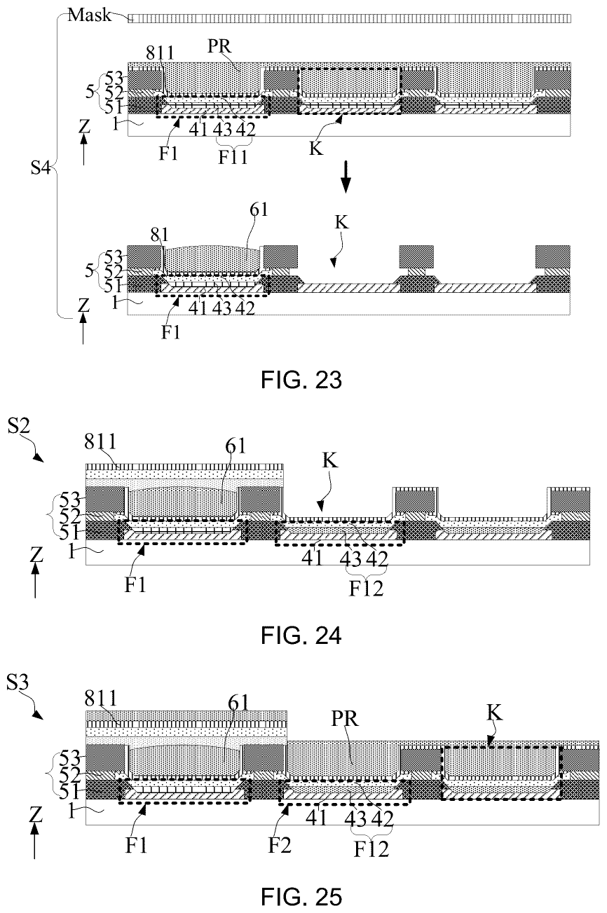

In S4, as shown in FIG. 23 which is a diagram showing a structure corresponding to the step S4 of the method for manufacturing the display panel 10 according to the embodiment shown in FIG. 16, portions, covering a region other than the regions of the first color light-emitting devices F1, of the first color light-emitting device film layer F11 and the first inorganic thin film 811 are removed based on the photoresist layer PR, so that remaining portions of the first color light-emitting device film layer F11 in the regions of the first color light-emitting devices F1 form the first color light-emitting devices F1, remaining portions of the first inorganic thin film 811 in the regions of the first color light-emitting devices F1 form corresponding portions of the first inorganic encapsulation layer 81, and remaining portions of the photoresist layer PR form a part of an optical structure 6. For example, the remaining portions of the photoresist layer PR form the optical portions 61 corresponding to the first color light-emitting devices F1.

After forming the first color light-emitting devices F1, the portions of the first inorganic encapsulation layer 81 corresponding to the first color light-emitting devices F1, and the optical portions 61 corresponding to the first color light-emitting devices F1, the steps S2 to S4 of the method for manufacturing the display panel 10 shown in FIG. 16 are repeated. In the case where the target color light-emitting devices Faa are the second color light-emitting devices F2, forming the second color light-emitting devices F2, the portions of the first inorganic encapsulation layer 81 corresponding to the second color light-emitting devices F2 and the optical portions 61 corresponding to the second color light-emitting devices F2 includes the following steps.

In S2, as shown in FIG. 24 which is a diagram showing a structure corresponding to the step S2 of the method for manufacturing the display panel 10 according to the embodiment shown in FIG. 16, a second color light-emitting device film layer F12 and the first inorganic thin film 811 are sequentially formed on the substrate 1 on which the plurality of pixel openings K have been formed.

In S3, as shown in FIG. 25 which is a diagram showing a structure corresponding to the step S3 of the method for manufacturing the display panel 10 according to the embodiment shown in FIG. 16, the photoresist layer PR is formed on the side of the first inorganic thin film 811 away from the substrate 1, and the photoresist layer PR covers regions of the second color light-emitting devices F2.

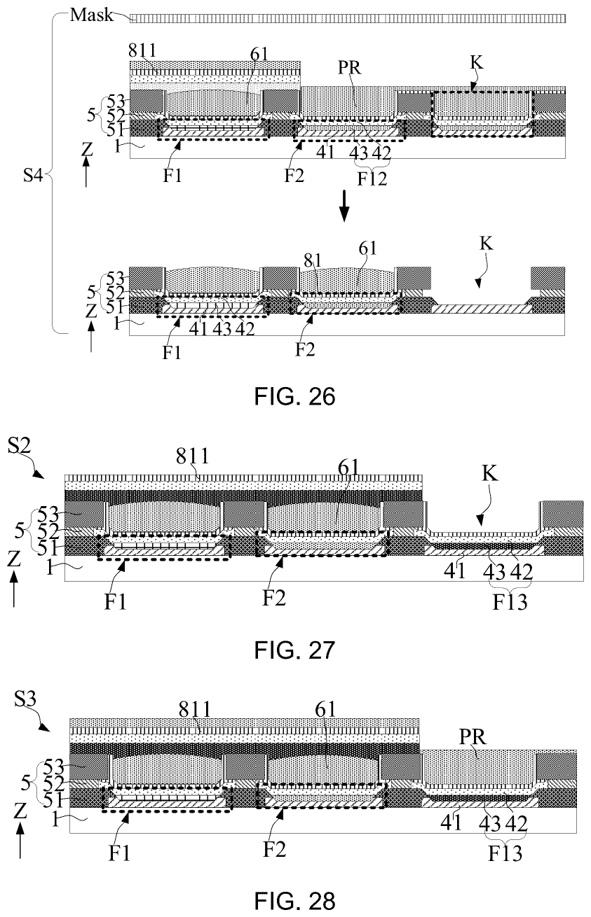

In S4, as shown in FIG. 26 which is a diagram showing a structure corresponding to the step S4 of the method for manufacturing the display panel 10 according to the embodiment shown in FIG. 16, portions, covering a region other than the regions of the second color light-emitting devices F2, of the second color light-emitting device film layer F12 and the first inorganic thin film 811 are removed based on the photoresist layer PR, so that remaining portions of the second color light-emitting device film layer F12 in the regions of the second color light-emitting devices F2 form the second color light-emitting devices F2, remaining portions of the first inorganic thin film 811 in the regions of the second color light-emitting devices F2 form corresponding portions of the first inorganic encapsulation layer 81, and remaining portions of the photoresist layer PR form a part of the optical structure 6. For example, the remaining portions of the photoresist layer PR form the optical portions 61 corresponding to the second color light-emitting devices F2.

After forming the second color light-emitting devices F2, the portions of the first inorganic encapsulation layer 81 corresponding to the second color light-emitting devices F2 and the optical portions 61 corresponding to the second color light-emitting devices F2, the steps S2 to S4 of the method for manufacturing the display panel 10 shown in FIG. 16 are repeated. In the case where the target color light-emitting devices Faa are the third color light-emitting devices F3, forming the third color light-emitting devices F3, the portions of the first inorganic encapsulation layer 81 corresponding to the third color light-emitting devices F3 and the optical portions 61 corresponding to the third color light-emitting devices F3 includes the following steps.

In S2, as shown in FIG. 27 which is a diagram showing a structure corresponding to the step S2 of the method for manufacturing the display panel 10 according to the embodiment shown in FIG. 16, a third color light-emitting device film layer F13 and the first inorganic thin film 811 are sequentially formed on the substrate 1 on which the plurality of pixel openings K have been formed.

In S3, as shown in FIG. 28 which is a diagram showing a structure corresponding to the step S3 of the method for manufacturing the display panel 10 according to the embodiment shown in FIG. 16, the photoresist layer PR is formed on the side of the first inorganic thin film 811 away from the substrate 1, and the photoresist layer PR covers regions of the third color light-emitting devices F3.

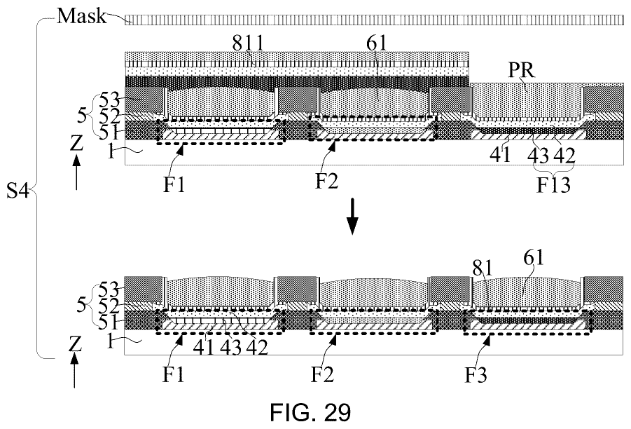

In S4, as shown in FIG. 29 which is a diagram showing a structure corresponding to the step S4 of the method for manufacturing the display panel 10 according to the embodiment shown in FIG. 16, portions, covering a region other than the regions of the third color light-emitting devices F3, of the third color light-emitting device film layer F13 and the first inorganic thin film 811 are removed based on the photoresist layer PR, so that remaining portions of the third color light-emitting device film layer F13 in the regions of the third color light-emitting devices F3 form the third color light-emitting devices F3, remaining portions of the first inorganic thin film 811 in the regions of the third color light-emitting devices F3 form corresponding portions of the first inorganic encapsulation layer 81, and remaining portions of the photoresist layer PR form a part of the optical structure 6. For example, the remaining portions of the photoresist layer PR form the optical portions 61 corresponding to the third color light-emitting devices F3.

The foregoing descriptions are merely specific implementations of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure should be determined by the protection scope of the claims.

1. A display panel, comprising:
a substrate;
an isolation structure located on a side of the substrate, wherein the isolation structure defines a plurality of pixel openings; and a light-emitting device is disposed in a pixel opening;
an encapsulation structure located on a side of the light-emitting device away from the substrate, wherein the encapsulation structure includes a first inorganic encapsulation layer, an organic encapsulation layer and a second inorganic encapsulation layer that are stacked in sequence in a direction away from the substrate; and
an optical structure located between the first inorganic encapsulation layer and the organic encapsulation layer, wherein the optical structure includes a plurality of light-transmissive optical portions, and a single optical portion is located in a single pixel opening.

2. The display panel according to claim 1, wherein a surface of the optical portion away from the substrate is closer to the substrate than a surface of the isolation structure away from the substrate; or
the surface of the optical portion away from the substrate is flush with the surface of the isolation structure away from the substrate.

3. The display panel according to claim 1, wherein the isolation structure includes a first sub-layer, a second sub-layer and a third sub-layer that are stacked in sequence in the direction away from the substrate;
a surface of the optical portion away from the substrate is farther away from the substrate than a surface of the second sub-layer away from the substrate.

4. The display panel according to claim 3, wherein a refractive index of a material of the optical portion is different from a refractive index of a material of the third sub-layer.

5. The display panel according to claim 4, wherein a refractive index of the optical portion is greater than or equal to 1.65, and a refractive index of the third sub-layer is less than or equal to 1.4; or
the refractive index of the optical portion is less than or equal to 1.4, and the refractive index of the third sub-layer is greater than or equal to 1.65.

6. The display panel according to claim 1, wherein a material of the optical portion includes photoresist.

7. The display panel according to claim 1, wherein the optical portion includes first particles, and a refractive index of the first particles is in a range of 1 to 2.

8. The display panel according to claim 1, wherein the optical portion is a filter color resist;
for a light-emitting device and a filter color resist that are located in a same pixel opening, a color of light transmitted by the filter color resist is the same as a color of light emitted by the light-emitting device.

9. The display panel according to claim 8, wherein the isolation structure includes a first sub-layer, a second sub-layer and a third sub-layer that are stacked in sequence in the direction away from the substrate;
at least the third sub-layer in the isolation structure includes a light-shielding material.

10. The display panel according to claim 9, wherein the second sub-layer includes a light-shielding material, and the third sub-layer includes a light-shielding material.

11. The display panel according to claim 2, wherein a first sub-layer of the isolation structure includes an insulating material, a third sub-layer of the isolation structure includes an insulating material, and a second sub-layer of the isolation structure includes a conductive material;
the light-emitting device includes a first electrode, a light-emitting portion and a second electrode that are stacked in sequence in the direction away from the substrate; and second electrodes of two adjacent light-emitting devices are connected through a portion of the second sub-layer of the isolation structure located between the two adjacent light-emitting devices.

12. The display panel according to claim 1, wherein a surface of the isolation structure away from the substrate is provided with a plurality of grooves, and a groove is communicated with at least one pixel opening.

13. The display panel according to claim 12, wherein at least one groove is arranged between two adjacent pixel openings, and the at least one groove is communicated with the two adjacent pixel openings.

14. The display panel according to claim 12, wherein one pixel opening is communicated with grooves, the grooves each extend in a direction away from the pixel opening, and the grooves are arranged around the pixel opening and arranged at intervals.

15. The display panel according to claim 14, wherein along a direction in which the grooves surround the pixel opening, a distance between two adjacent grooves is equal.

16. The display panel according to claim 12, wherein the isolation structure includes a first sub-layer, a second sub-layer and a third sub-layer that are stacked in sequence in the direction away from the substrate; and a depth of the groove is less than or equal to a thickness of the third sub-layer of the isolation structure.

17. The display panel according to claim 1, wherein the isolation structure includes a first sub-layer, a second sub-layer and a third sub-layer that are stacked in sequence in the direction away from the substrate; a material of the third sub-layer of the isolation structure includes a hydrophobic material or an oleophobic material; and a material of the optical structure includes a hydrophobic material or an oleophobic material.

18. The display panel according to claim 1, wherein the isolation structure includes a first sub-layer, a second sub-layer and a third sub-layer that are stacked in sequence in the direction away from the substrate;
the light-emitting device includes a first electrode, a light-emitting portion and a second electrode that are stacked in sequence in the direction away from the substrate;
the first sub-layer covers a part of the first electrode.

19. A method for manufacturing a display panel, comprising:
forming an isolation structure on a side of a substrate, the isolation structure defining a plurality of pixel openings;
sequentially forming a target color light-emitting device film layer and a first inorganic thin film on the substrate on which the plurality of pixel openings have been formed;
forming a photoresist layer on a side of the first inorganic thin film away from the substrate, the photoresist layer covering regions of target color light-emitting devices; and
based on the photoresist layer, removing portions, covering a region other than the regions of the target color light-emitting devices, of the target color light-emitting device film layer and the first inorganic thin film, so that remaining portions of the target color light-emitting device film layer in the regions of the target color light-emitting devices form the target color light-emitting devices, remaining portions of the first inorganic thin film in the regions of the target color light-emitting devices form corresponding portions of a first inorganic encapsulation layer, and remaining portions of the photoresist layer form a part of an optical structure.

20. A display apparatus, comprising:
the display panel according to claim 1; and
a cover plate disposed on a light exit side of the display panel.
